(19) United States
(12) Patent Application Publication
(10) Pub. No.: US 2008/0254593 A1
(43) Pub. Date: Oct. 16, 2008

(54) Method for Fabricating Isolation Layer in Semiconductor Device

(75) Inventors: Byung Soo Eun, Seoul (KR); Jung Suk Lee, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-Si (KR)

(21) Appl. No.: 11/963,909

(22) Filed: Dec. 24, 2007

(30) Foreign Application Priority Data
Apr. 10, 2007 (KR) 10-2007-0035078

(51) Int. Cl. H01L 21/76

(52) U.S. Cl. 438/425; 257/E21.54

(57) ABSTRACT

A method of fabricating an isolation layer in a semiconductor device includes forming a trench in a semiconductor substrate, depositing a high-density plasma (HDP) oxide layer partially filling the trench by supplying an HDP deposition source, etching an overhang generated while the HDP oxide layer is deposited using a fluorine-containing etching gas, depositing a liner HDP oxide layer on the HDP oxide layer by supplying an inert gas and an HDP deposition source such that fluorine (F) is trapped in the liner HDP oxide layer, performing an isotropic etching on an overhang portion of a side surface of the HDP oxide layer using the fluorine (F) trapped in the liner HDP oxide layer, and forming an HDP capping layer on the liner HDP oxide layer to fill a remaining portion of the trench.

### CROSS-REFERENCE TO RELATED APPLICATION

The priority of Korean patent application number 10-2007-0035078, filed on Apr. 10, 2007, the disclosure of which is incorporated by reference in its entirety is claimed.

### BACKGROUND OF THE INVENTION

The invention relates to a semiconductor device and, more particularly, to a method of fabricating an isolation layer in a semiconductor device capable of increasing a gap-fill margin and a process margin of the isolation layer.

In the development of semiconductor memory devices such as dynamic random access memory (DRAM) devices, an isolation process is essential to control the retention time of data in the device. Particularly, along with the trend of high integration of semiconductor devices and miniaturization of patterns, a shallow trench isolation (STI) process for fabricating devices having a small line width and excellent isolation characteristics is of increasing importance. In the STI process, generally, an isolation layer is formed by performing an exposure process and an etching process to form a trench having a specified depth in a semiconductor substrate, filling an insulating layer in the trench, and performing a planarization process. On the other hand, as the design rule of semiconductor devices becomes finer along with the trend of high integration of semiconductor devices, space for forming the isolation layer is rapidly reduced, thereby decreasing a gap-fill margin. Accordingly, for example, a deposition-etch-deposition method is used as a gap-fill method to fill the trench having a small space margin. Further, a material having excellent gap-fill characteristics, for example, a high density plasma (HDP) oxide layer is used as an insulating layer to fill the trench. However, even in the deposition-etch-deposition method, voids may be generated in the insulating layer buried in the trench due to insufficient margins. Specifically, in a deposition process of depositing the insulating layer to fill the trench, an overhang may be formed at an upper portion of the trench, and the opening of the trench is narrowed by the overhang before the trench is entirely filled, thereby generating a void.

To overcome the difficulty in filling the trench, one approach to depositing a high density plasma (HDP) oxide layer uses a method of repeated deposition of the HDP oxide layer and an etching process for etching the overhang formed at the upper portion of the trench. In this case, the overhang of the trench is etched using an etching gas. However, even in this method using an etching gas, it is difficult to perfectly remove the overhang formed in the trench. Further, since the etching gas has high directionality, the attack of the etching gas is generated from the upper portion of the trench and the etching gas can attack a pad nitride layer and a liner nitride layer at the upper portion of the trench. The liner nitride layer prevents an oxygen source from penetrating a trench isolation layer in the following oxidation process for forming a gate insulating layer, thereby reducing leakage current and improving the refresh characteristics of the DRAM. However, when the liner nitride layer is damaged due to the attack of the etching gas, the semiconductor substrate is additionally oxidized during the following oxidation and heat processes, thereby causing refresh time reduction and a change in a threshold voltage due to an outward diffusion of doped impurities. Further, it may cause problems such as gate oxide integrity (GOI) degradation. When the pad nitride layer is damaged, horn defects occur, thereby causing problems such as a change in a threshold voltage.

### BRIEF SUMMARY OF THE INVENTION

The invention provides a method of fabricating an isolation layer in a semiconductor device capable of increasing a gap-fill margin and a process margin of the isolation layer and simplifying the whole process by overcoming the problems occurring in a process of etching an overhang in forming a trench isolation layer.

The invention provides a method of fabricating an isolation layer in a semiconductor device comprising: forming a trench in a semiconductor substrate; forming an HDP oxide layer partially filling the trench by supplying an HDP deposition source; etching an overhang generated while the HDP oxide layer is deposited using a fluorine-containing etching gas; forming a liner HDP oxide layer on the HDP oxide layer by supplying an inert gas and a HDP deposition source such that fluorine (F) is trapped in the liner HDP oxide layer; performing an isotropic etching on an overhang portion of a side surface of the HDP oxide layer using the fluorine (F) trapped in the liner HDP oxide layer; and forming an HDP capping layer on the liner HDP oxide layer to fill a remaining portion of the trench.

The HDP deposition source preferably includes a source gas containing a silane (SiH₄) gas and an oxygen (O₂) gas, a carrier gas containing helium (He), and a reduction gas containing hydrogen (H₂).

Etching an overhang preferably includes supplying the etching gas containing helium (He) gas and hydrogen (H₂) gas to etch the overhang.

The depositing of a HDP oxide layer and etching an overhang are preferably repeated four or more times.

The fluorine-containing etching gas preferably comprises nitrogen trifluoride (NF₃) gas.

The inert gas preferably comprises Ar gas.

The liner HDP oxide layer is preferably deposited to have a thickness of 80 Å to 120 Å.

The liner HDP oxide layer is preferably deposited at a lower deposition rate than that when the HDP oxide layer is deposited.

Forming an HDP oxide layer, etching an overhang, forming a liner HDP oxide layer, performing isotropic etching, and forming a HDP capping layer are preferably performed as an in-situ process in a single high density plasma chamber.

Before forming an HDP oxide layer partially filling the trench, the method preferably further includes forming a sidewall oxide layer on a sidewall of the trench; and forming a liner nitride layer on the sidewall oxide layer.

The isotropic etching on an overhang portion of a side surface of the HDP oxide layer using the trapped fluorine (F) is preferably repeated three or more times.

### BRIEF DESCRIPTION OF THE DRAWINGS

The invention will be more clearly understood from the following detailed description taken in conjunction with the accompanying drawings, in which:

FIGS. 1 to 9 are diagrams for explaining a method for fabricating an isolation layer in a semiconductor device in accordance with one embodiment of the invention.

### DETAILED DESCRIPTION OF THE INVENTION

Preferred embodiments of the invention are described below in detail with reference to the accompanying drawings. These embodiments are used only for illustrative purposes, and the invention is not limited thereto. In the drawings, a thickness is enlarged to clearly represent a plurality of layers and regions. Throughout the specification, like reference numerals designate like parts having practically the same functions.

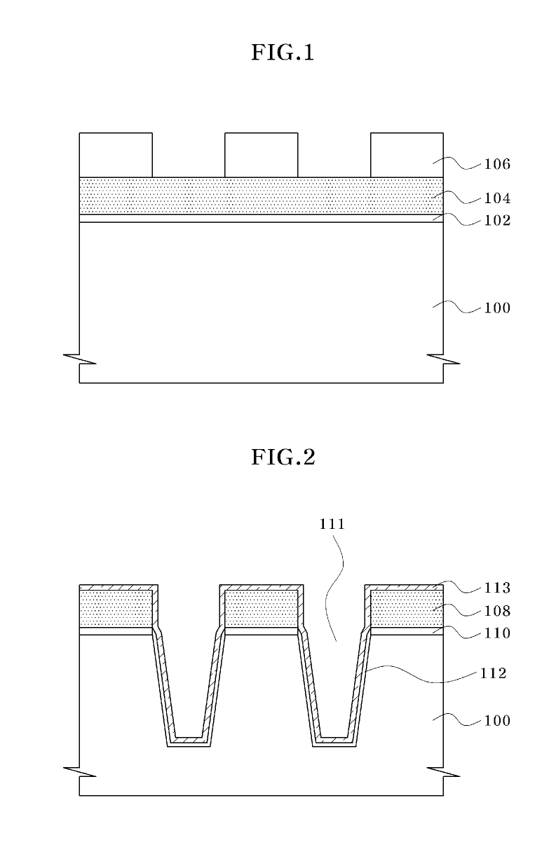

FIGS. 1 to 9 are diagrams for explaining a method for fabricating an isolation layer in a semiconductor device in accordance with one embodiment of the invention.

Referring to FIG. 1, a pad oxide layer 102 and a pad nitride layer 104 are deposited on a semiconductor substrate 100. The pad oxide layer 102 serves to relieve stress on the semiconductor substrate 100 due to an attractive force of the pad nitride layer 104. Then, a mask pattern 106 is formed to selectively expose certain regions of the pad oxide layer 102. Specifically, a photoresist layer is coated on the pad nitride layer 104 and an exposure process and a developing process are performed using a photomask, thereby forming the mask pattern 106 having openings to expose certain portions of the surface of the pad nitride layer 104.

Referring to FIG. 2, a trench 111 having a predetermined depth is formed in the semiconductor substrate 1 00 using the mask pattern 106 as an etching mask. Specifically, the exposed portions of the pad nitride layer 104 are etched using the mask pattern 106 as an etching mask to form a pad nitride pattern 108. Then, the mask pattern 106 is removed using a stripping process. Subsequently, the exposed regions of the pad oxide layer 102 are etched using the pad nitride pattern 108 to form a pad oxide pattern 110 exposing certain regions of the semiconductor substrate 100. Then, the exposed regions of the semiconductor substrate 100 are etched using the pad nitride pattern 108 and the pad oxide pattern 1 10 as an etching mask to form the trench 111 having a predetermined depth.

Next, a sidewall oxide layer 112 is formed on the exposed sidewall of the trench 111 by performing an oxidation process. A liner nitride layer 113 is deposited on the semiconductor substrate 100 including the sidewall oxide layer 112. The sidewall oxide layer 112 serves as a buffer layer to prevent stress generated when the liner nitride layer 113 is deposited directly on the semiconductor substrate 100. The liner nitride layer 113 prevents an oxygen source from penetrating a trench isolation layer in the following oxidation process for forming a gate insulating layer, thereby improving the refresh characteristics of a DRAM device.

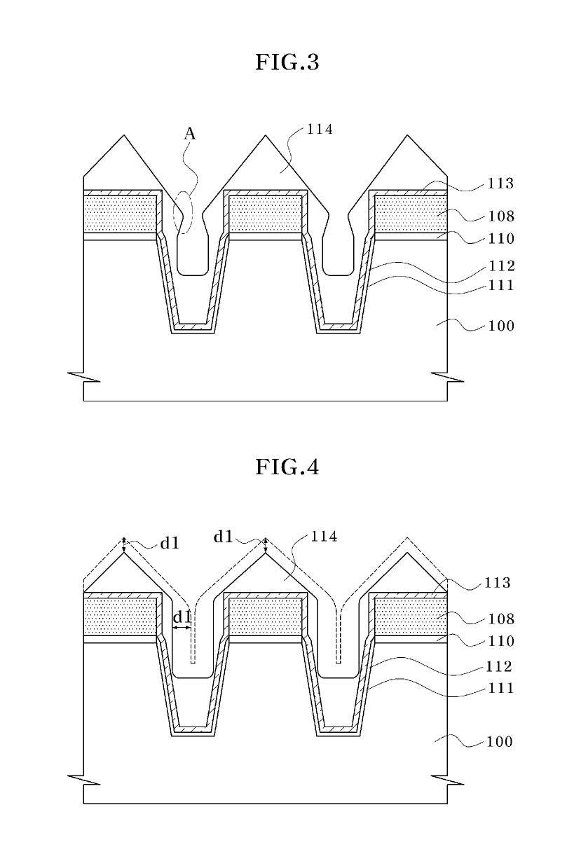

Referring to FIG. 3, a first deposition process is carried out to form a first HDP oxide layer 114 partially filling the trench 111.

Specifically, according to a preferred embodiment, the semiconductor substrate 100 including the trench 111 is loaded into a high density plasma (HDP) chamber. Then, a HDP deposition source is supplied into the chamber. The HDP deposition source preferably includes a source gas containing silane (SiH₄) gas and oxygen (O₂) gas, a carrier gas containing helium (He) and a reduction gas containing hydrogen (H₂). In this case, the oxygen (O₂) gas serving as a source gas is preferably supplied at a flow rate of 50 sccm to 60 sccm. Further, the silane (SiH₄) gas is preferably supplied at a flow rate of 10 sccm to 20 sccm at the top portion of the chamber and is preferably supplied at a flow rate of 20 sccm to 30 sccm at the sides of the chamber. The helium (He) gas serving as a carrier gas is preferably supplied at a flow rate of 25 sccm to 35 sccm at the top portion of the chamber and is preferably supplied at a flow rate of 200 sccm to 250 sccm at the sides of the chamber. The hydrogen (H₂) gas serving as a reduction gas is preferably supplied at a flow rate of 100 sccm to 150 sccm. In this case, in order to generate a plasma, top power is preferably applied in a range of 4500W to 5000 W and side power is preferably applied in a range of 2500W to 3500 W. Also, bottom power is preferably applied in a range of 1000W to 1500 W at the bottom of the chamber. Thus, the first HDP oxide layer 114 is deposited in the trench 111 to preferably have a thickness of 600 Å to 1000 Å by the HDP deposition source and power applied to the chamber. In this case, the first HDP oxide layer 114 partially filling the trench 111 may also be deposited on the top portion of the pad nitride pattern 108 and the side surface of the pad oxide pattern 110, thereby causing an overhang A at the upper portion of the trench 111.

Referring to FIG. 4, a first etching process is performed to etch the overhang a generated in the first deposition process such that the thickness of the first HDP oxide layer 114 is decreased by a partial thickness d1. During the first deposition process, the first HDP oxide layer 114 may also be deposited on the top portion of the pad nitride pattern 108 and the side surface of the pad oxide pattern 110, and the overhang A (see FIG. 3) may be formed to be protruded from an opening of the trench 111. If the overhang A is not removed, the opening of the trench 111 is narrowed by the overhang A during the deposition process. Accordingly, it is hard to sufficiently fill the trench 111, thereby causing defects such as the void in the trench 111.

Thus, the first etching process is performed on the first HDP oxide layer 114 after the first deposition process is carried out, thereby removing the overhang A. Specifically, after the first deposition process, an etching gas is supplied into the chamber containing the semiconductor substrate 100. A fluorine-containing gas (F-based gas), for example, nitrogen trifluoride (NF₃) gas is preferably used as an etching gas and is preferably supplied together with hydrogen (H₂) gas and helium (He) gas. In this case, the nitrogen trifluoride (NF₃) gas is preferably supplied at a flow rate of 50 sccm to 150 sccm and the hydrogen (H₂) gas is preferably supplied at a flow rate of 50 sccm to 150 sccm. Further, the helium (He) gas is preferably supplied at a flow rate of 80 sccm to 90 sccm at the sides of the chamber. In this case, in order to generate a plasma, top power is preferably applied in a range of 800W to 1200 W and side power is preferably applied in a range of 2500 W to 3500 W. Also, bottom power is preferably applied in a range of 600 W to 700 W at the bottom of the chamber. Accordingly, an etching plasma generated in the chamber is adsorbed onto the semiconductor substrate 100.

The first HDP oxide layer 114 is etched by the etching gas and power applied to the chamber such that the thickness of the first HDP oxide layer 114 shown in FIG. 3 is decreased by a partial thickness d₁ of, for example, 200 Å to 250 Å. Then, the overhang A formed at the upper portion of the trench 111 is removed to a certain extent. Subsequently, the deposition process and the etching process described with reference to FIGS. 3 and 4 are preferably repeated four or more times, thereby forming a HDP oxide layer profile suitable for gap filling. In this case, the deposition and the etching processes are preferably repeated for a short period of time, thereby filling the trench by repeatedly depositing the HDP oxide layer with a fine thickness.

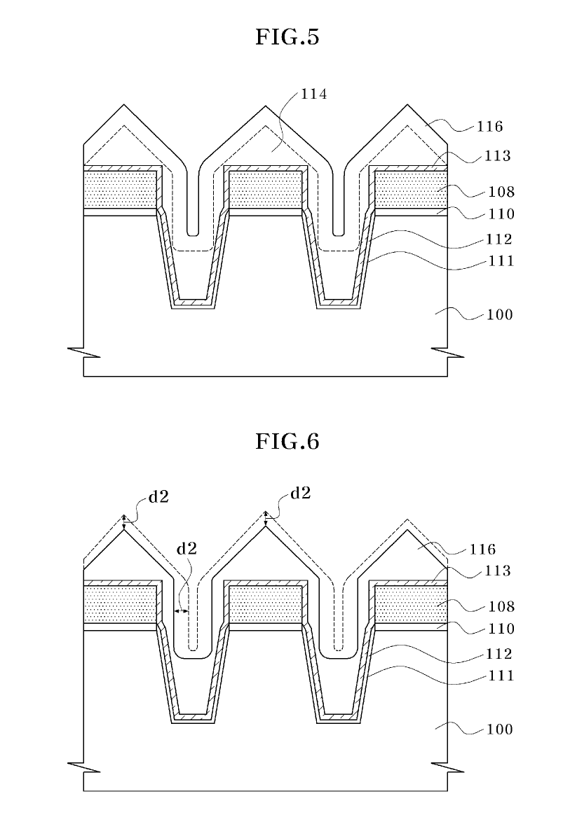

Referring to FIG. 5, a second deposition process is carried out to form a second HDP oxide layer 116 on the first HDP oxide layer 114 formed by the first deposition process and the first etching process. The second HDP oxide layer 116 is preferably formed by supplying the same HDP deposition source as that used in the first deposition process into the chamber after the first deposition process and the first etching process are carried out.

Specifically, the HDP deposition source preferably includes a source gas containing a silane (SiH₄) gas and an oxygen (O₂) gas, a carrier gas containing helium (He), and a reduction gas containing hydrogen (H₂). In this case, the oxygen (O₂) gas serving as a source gas is preferably supplied at a flow rate of 50 sccm to 60 sccm. Further, the silane (SiH₄) gas is preferably supplied at a flow rate of 10 sccm to 20 sccm at the top portion of the chamber and is preferably supplied at a flow rate of 20 sccm to 30 sccm at the sides of the chamber. The helium (He) gas serving as a carrier gas is preferably supplied at a flow rate of 25 sccm to 35 sccm at the top portion of the chamber and is preferably supplied at a flow rate of 200 sccm to 250 sccm at the sides of the chamber. The hydrogen (H₂) gas serving as a reduction gas is preferably supplied at a flow rate of 100 sccm to 150 sccm. In this case, in order to generate a plasma, top power is preferably applied in a range of 4500 W to 5000 W and side power is preferably applied in a range of 2500W to 3500 W. Also, bottom power is preferably applied in a range of 1000W to 1500 W at the bottom of the chamber. The second HDP oxide layer 116 is preferably deposited on the first HDP oxide layer 114 to have a specified thickness of, for example, 600 Å to 1000 Å by the HDP deposition source and power applied to the chamber. The second HDP oxide layer 116 is formed to achieve bottom-up filling in the trench at the maximum level.

Referring to FIG. 6, a second etching process is performed to etch any overhang generated while the second HDP oxide layer 116 is formed.

Specifically, after the second deposition process, an etching gas preferably containing a fluorine-containing gas is supplied into the chamber. The etching gas preferably includes a fluorine-containing gas (F-based gas) such as a nitrogen trifluoride (NF₃) gas, a hydrogen (H₂) gas, and a helium (He) gas. In this case, the nitrogen trifluoride (NF₃) gas is preferably supplied at a flow rate of 50 sccm to 150 sccm and the hydrogen (H₂) gas is preferably supplied at a flow rate of 50 sccm to 150 sccm. Further, the helium (He) gas is preferably supplied at a flow rate of 80 sccm to 90 sccm at the sides of the chamber. In this case, in order to generate a plasma, top power is preferably applied in a range of 800W to 1200 W and side power is preferably applied in a range of 2500W to 3500 W. Also, bottom power is preferably applied in a range of 600W to 700 W at the bottom of the chamber. Accordingly, an etching plasma generated in the chamber is adsorbed onto the semiconductor substrate 100 to etch the overhang.

The second HDP oxide layer 116 is etched by the etching gas and power applied to the chamber such that the thickness of the second HDP oxide layer 116 is decreased by a partial thickness d₂ of, for example, 40 Å to 80 Å.

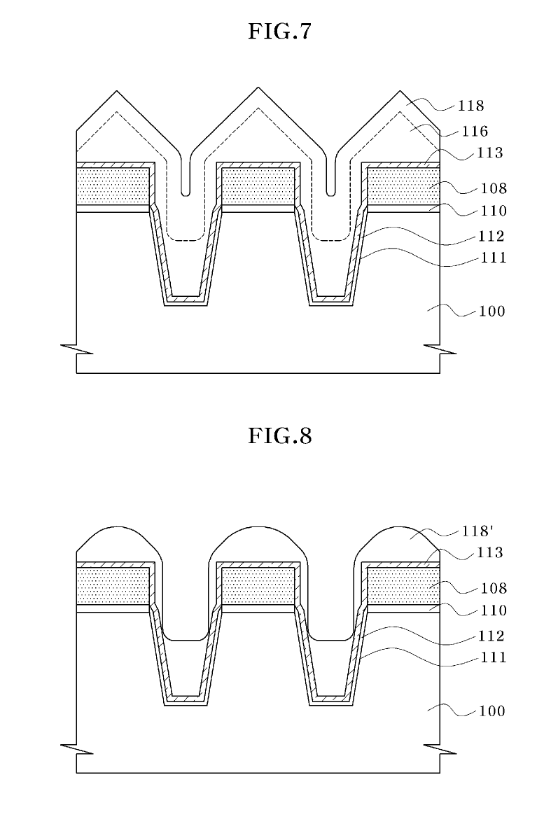

Referring to FIG. 7, after the second etching process is performed, a liner HDP oxide layer 118 preferably having a thickness of 80 Å to 120 Å is deposited on the second HDP oxide layer 116. The liner HDP oxide layer 118 is preferably deposited by supplying an inert gas and a HDP deposition source into the chamber.

The inert gas, for example, an Ar gas is preferably supplied at a flow rate of 100 sccm to 200 sccm. The HDP deposition source preferably includes a source gas containing silane (SiH₄) gas and oxygen (O₂) gas, a carrier gas containing helium (He), and a reduction gas containing hydrogen (H₂). In this case, the oxygen (O₂) gas serving as a source gas is preferably supplied at a flow rate of 100 sccm to 200 sccm. Further, the silane (SiH₄) gas is preferably supplied at a flow rate of 20 sccm to 30 sccm at the sides of the chamber. The helium (He) gas serving as a carrier gas is preferably supplied at a flow rate of 100 sccm to 150 sccm at the top portion of the chamber and is preferably supplied at a flow rate of 100 sccm to 150 sccm at the sides of the chamber. The hydrogen (H₂) gas serving as a reduction gas is preferably supplied at a flow rate of 80 sccm to 120 sccm. In this case, in order to generate a plasma, top power is preferably applied in a range of 3000 W to 4000 W and side power is preferably applied in a range of 3000 W to 4000 W. Also, bottom power is preferably applied in a range of 500 W to 1300 W at the bottom of the chamber. The liner HDP oxide layer 118 is deposited on the second HDP oxide layer 116 to have a specified thickness of, for example, 80 Å to 120 Å by the HDP deposition source and power applied to the chamber. In this case, the liner HDP oxide layer 118 is preferably deposited at a lower deposition rate than those in the first and second deposition processes.

While the etching process is performed using an etching gas containing a nitrogen trifluoride (NF₃) gas, the second HDP oxide layer 116 preferably includes a specified amount of fluorine (F). Conventionally, in order to remove the fluorine (F) included in the HDP oxide layer, generally, only oxygen (O₂) gas is discharged for an etch stop. However, in this embodiment, the second HDP oxide layer 116 is deposited and then the liner HDP oxide layer 118 is deposited on the second HDP oxide layer 116. Accordingly, non-discharged fluorine (F) is trapped in the liner HDP oxide layer 118 and the trapped fluorine (F) loses directionality. Isotropic etching is performed by the fluorine (F) having no directionality to remove the HDP oxide layer deposited on the upper side wall of the trench 111 as in wet etching. Thus, as shown in FIG. 8, a second HDP oxide layer 118′ is formed into a profile having a large margin at the opening of the trench. The isotropic etching process, wherein the liner HDP oxide layer 118 is formed to trap the fluorine (F) and the liner HDP oxide layer 118 is isotropically etched by the trapped fluorine (F), is preferably repeated three or more times. Thus, it is possible to form a profile having a large margin at the opening of the trench.

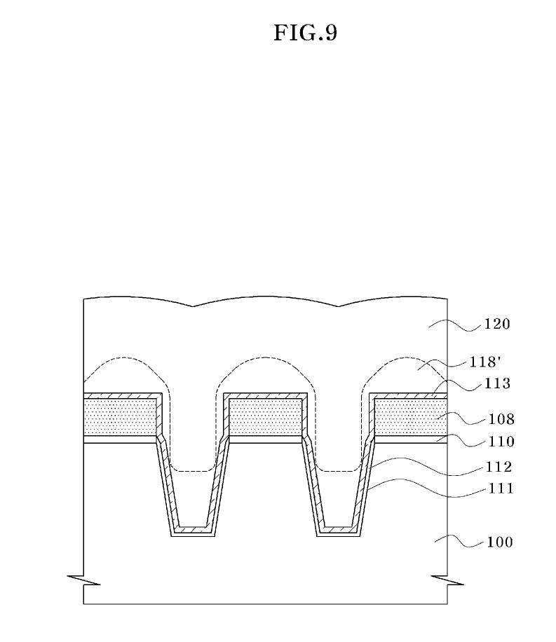

Referring to FIG. 9, an HDP capping layer 120 is deposited on the second HDP oxide layer 118′ to fill a remaining portion of the trench 111. The HDP capping layer 120 is preferably formed by the same deposition and etching processes as when the HDP oxide layer is formed.

Specifically, an HDP deposition source is supplied into the chamber. The HDP deposition source preferably includes a source gas containing a silane (SiH₄) gas and an oxygen (O₂) gas, a carrier gas containing helium (He) and a reduction gas containing hydrogen (H₂). In this case, the oxygen (O₂) gas serving as a source gas is preferably supplied at a flow rate of 50 sccm to 60 sccm. Further, the silane (SiH₄) gas is preferably supplied at a flow rate of 10 accm to 20 sccm at the top portion of the chamber and is preferably supplied at a flow rate of 20 sccm to 30 sccm at the sides of the chamber. The helium (He) gas serving as a carrier gas is preferably supplied at a flow rate of 25 sccm to 35 sccm at the top portion of the chamber and preferably supplied at a flow rate of 200 sccm to 250 sccm at the sides of the chamber. The hydrogen (H₂) gas serving as a reduction gas is preferably supplied at a flow rate of 100 sccm to 150 sccm. In this case, in order to generate a plasma, top power is preferably applied in a range of 4500 W to 5000 W and side power is preferably applied in a range of 2500 W to 3500 W. Also, bottom power is preferably applied in a range of 1000 W to 1500 W at the bottom of the chamber. Thus, a HDP oxide layer is deposited to have a specified thickness of, for example, 600 Å to 1000 Å by the HDP deposition source and power applied to the chamber.

Next, an etching process is performed on the deposited HDP oxide layer. Specifically, an etching gas is supplied into the chamber. The etching gas preferably includes nitrogen trifluoride (NF₃) gas, hydrogen (H₂) gas and helium (He) gas. In this case, the nitrogen trifluoride (NF₃) gas is preferably supplied at a flow rate of 50 sccm to 150 sccm and the hydrogen (H₂) gas is preferably supplied at a flow rate of 50 sccm to 150 sccm. Further, the helium (He) gas is preferably supplied at a flow rate of 80 sccm to 90 sccm at the sides of the chamber. In this case, in order to generate a plasma, top power is preferably applied in a range of 800 W to 1200 W and side power is preferably applied in a range of 2500 W to 3500 W. Also, bottom power is preferably applied in a range of 600 W to 700 W at the bottom of the chamber. Accordingly, an etching plasma is generated in the chamber to etch the overhang.

The HDP oxide layer is etched by the etching gas and power applied to the chamber such that the thickness of the HDP oxide layer is decreased by a partial thickness of 200 Å to 250 Å, for example. The deposition process and the etching process are preferably repeated four or more times, thereby forming the HDP capping layer 120 to entirely fill the trench 111. In this case, the deposition and the etching processes are preferably repeated for a short period of time, thereby filling the trench by repeatedly depositing the HDP oxide layer with a fine thickness. Meanwhile, all processes for forming the first HDP oxide layer to the HDP capping layer are preferably performed as an in-situ process in a single chamber.

In the method for fabricating the isolation layer in the semiconductor device according to the illustrated embodiment of the invention, after an etching process is performed using a nitrogen trifluoride (NF₃) gas, fluorine (F) is not discharged to the outside using an oxygen gas, and the liner HDP oxide layer is deposited on the HDP oxide layer at a low deposition rate. Then, the fluorine (F) in the nitrogen trifluoride (NF₃) gas is trapped in the liner HDP oxide layer and the trapped fluorine (F) is used as an isotropic etching gas. Accordingly, it is possible to etch an overhang of the HDP oxide layer at the upper portion of the trench. That is, the process can be simplified by omitting wet etching performed for the isotropic etching. Further, all deposition and etching processes are performed in a single chamber, thereby preventing an increase in equipment investment and simplifying the entire process.

As described above, in the method for fabricating the isolation layer in the semiconductor device according to the illustrated embodiment of the invention, fluorine (F) in the nitrogen trifluoride (NF₃) gas is used as an isotropic etching gas, thereby increasing a process margin of the trench isolation layer. The deposition and etching processes of the HDP oxide layer are preferably performed in a single chamber, thereby simplifying the whole process.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A method of fabricating an isolation layer in a semiconductor device, comprising:
forming a trench in a semiconductor substrate;
forming a high density plasma (HDP) oxide layer partially filling the trench by supplying an HDP deposition source;
etching an overhang generated while the HDP oxide layer is deposited using a fluorine-containing etching gas;
forming a liner HDP oxide layer on the HDP oxide layer by supplying an inert gas and a HDP deposition source such that fluorine (F) is trapped in the liner HDP oxide layer;
performing an isotropic etching on an overhang portion of a side surface of the HDP oxide layer using the fluorine (F) trapped in the liner HDP oxide layer; and
forming an HDP capping layer on the liner HDP oxide layer to fill a remaining portion of the trench.

2. The method according to claim 1, wherein the HDP deposition source includes a sources gas containing a silane (SiH₄) gas and an oxygen (O₂) gas, a carrier gas containing helium (He), and a reduction gas containing hydrogen (H₂).

3. The method according to claim 1, wherein etching an overhang comprises:
supplying the etching gas containing a helium (He) gas and a hydrogen (H₂) gas to etch the overhang.

4. The method according to claim 1, wherein depositing an HDP oxide layer and etching an overhang are repeated four or more times.

5. The method according to claim 1, wherein the fluorine-containing etching gas comprises a nitrogen trifluoride (NF₃) gas.

6. The method according to claim 1, wherein the inert gas comprises Ar gas.

7. The method according to claim 1, comprising depositing the liner HDP oxide layer to have a thickness of 80 Å to 120 Å.

8. The method according to claim 1, comprising depositing the liner HDP oxide layer at a lower deposition rate than that when the HDP oxide layer is deposited.

9. The method according to claim 1, wherein forming an HDP oxide layer, etching an overhang, forming a liner HDP oxide layer, performing isotropic etching, and forming an HDP capping layer are performed as an in-situ process in a single HDP chamber.

10. The method according to claim 1, further comprising, before forming an HDP oxide layer partially filling the trench:
forming a sidewall oxide layer on a sidewall of the trench; and
forming a liner nitride layer on the sidewall oxide layer.

11. The method according to claim 1, wherein performing an isotropic etching on an overhung portion of a side surface of the HDP oxide layer using the trapped fluorine (F) is repeated three or more times.
